(19) United States
(12) Patent Application Publication
(10) Pub. No.: US 2015/0102261 A1
(43) Pub. Date: Apr. 16, 2015

(54) PHOSPHOR MIXTURE HAVING OPTIMIZED COLOR RENDERING PROPERTIES AND EMISSION INTENSITY OF EMITTED LIGHT IN VISIBLE REGION

(71) Applicant: UBE MATERIAL INDUSTRIES, LTD., Ube-shi, Yamaguchi (JP)

(72) Inventors: Kouichi Fukuda, Ube-shi (JP); Jin Amagai, Ube-shi (JP); Toru Inagaki, Ube-shi (JP); Rika Nogita, Ube-shi (JP); Kenji Arima, Ube-shi (JP)

(21) Appl. No.: 14/402,868

(22) PCT Filed: May 22, 2013
(86) PCT No.: PCT/JP2013/064287

§ 371 Date: Nov. 21, 2014

(30) Foreign Application Priority Data
May 22, 2012 (JP) 2012-116824

(51) Int. Cl. C09K 11/77; C09K 11/02; H01L 33/50

(52) U.S. Cl. CPC C09K 11/7734; H01L 33/504; C09K 11/025
USPC 252/301.4 F

(57) ABSTRACT

A phosphor mixture comprising at least two phosphors A, B which give an emission spectrum having the maximum emission peak in the visible region, in which a wavelength of the maximum emission peak of the phosphor A differs from that of the maximum emission peak of the phosphor B by not more than 50 nm, and in which the maximum emission peak of the phosphor A has an emission intensity less than that of the phosphor B and the maximum emission peak of the phosphor A shows a half-width more than a half-width of that of the phosphor B gives an light emission having the maximum emission peak whose emission intensity is higher than that of the phosphor A and whose half-width is broader than that of the phosphor B.

### FIELD OF THE INVENTION

The present invention relates to a phosphor mixture having optimized color rendering properties and emission intensity in visible region.

### BACKGROUND OF THE INVENTION

A white light-emitting diode (white LED) is known as a light emitting device which utilizes a visible light source comprising a phosphor having a maximum emission peak in the visible region. As the white LED, there is known an LED of double color-mixing type which utilizes a combination of a semiconductor light-emitting element capable of emitting a blue light upon receipt of electric energy and a yellow light-emitting phosphor composition dispersed in a resinous binder. A portion of the blue light emitted by the semiconductor light-emitting element and a yellow light emitted by the phosphor upon excitation with another portion of the blue light are mixed together to produce a white light. However, there is a problem in the white light produced by the double color-mixing type LED in that the wavelength range of the produced white light is narrower than that of the sunlight. For this reason, there is recently developed an LED of triple color-mixing type which utilizes a combination of a semiconductor light-emitting element capable of emitting a light of a wavelength in the range of 350 nm to 430 nm upon receipt of electric energy and a phosphor-containing resin composition comprising a blue light-emitting phosphor, a green light-emitting phosphor and a red light-emitting phosphor dispersed in a resinous binder such as epoxy resin or silicone resin. In the triple color-mixing type LED, the phosphors are excited with a light emitted by the semiconductor light-emitting element to produce a blue light, a green light and a red light, which are then mixed to produce a white light having a broader wavelength range.

JP 2004-168996 A discloses a light-emitting device of triple light-mixing type for the use as a back light of a liquid display, which comprises at least one blue light-emitting phosphor, at least one green light-emitting phosphor and at least one red light-emitting phosphor. This publication discloses a great number of compounds for each of the blue light-emitting phosphor, green light-emitting phosphor and red light-emitting phosphor, and describes these compounds can be employed in combination. However, there is seen no teaching on specific combinations of the phosphors.

Thus, it is desired that the white LED gives an emission intensity analogous to that of the sunlight. This means that the white LED shows a color rendering property analogous to that of the sunlight. Therefore, it is required that the phosphors employed for the white LED give a light of not only high emission intensity but also a maximum emission peak of broad half-width.

As a result of studies, the inventors of the present invention have noted, however, that the known phosphors are not satisfactory for the use as phosphors for the use as those for constituting a white LED because phosphors giving a light of high emission intensity shows a maximum emission peak with a narrow half-width, whereas phosphors showing a maximum emission peak with a broad half-width gives a light of low emission intensity.

### SUMMARY OF THE INVENTION

For the purpose of solving the above-mentioned problem, the inventors have studied a mixture of two or more phosphors emitting lights of analogous colors. As a result of the studies, the inventors have found that phosphor mixtures showing optimized color rendering property and emission intensity of emitted light in the visible region can be obtained by combining at least two phosphors whose maximum emission peaks are observed at wavelengths differing from each other by 50 nm or less under such conditions that one phosphor shows a maximum emission peak having a relatively high emission intensity but a relatively narrow half-width and another phosphor shows a maximum emission peak having a relatively broad half-width but a relatively low emission intensity.

The present invention has been established on the basis of the above-mentioned finding.

Accordingly, the invention resides in a phosphor mixture comprising at least two phosphors A and B which give an emission spectrum having the maximum emission peak in the visible region, wherein a wavelength of the maximum emission peak of the phosphor A differs from that of the maximum emission peak of the phosphor B by not more than 50 nm, and wherein the maximum emission peak of the phosphor A has an emission intensity less than an emission intensity of the maximum emission peak of the phosphor B and the maximum emission peak of the phosphor A shows a half-width broader than a half-width of the maximum emission peak of the phosphor B.

Preferred embodiments of the invention are described below:

(1) The phosphor B has an excitation intensity at a wavelength of the maximum emission peak appearing in the emission spectrum of the phosphor A not more than 5% of an excitation intensity at a wavelength of 400 nm and the phosphor A has an excitation intensity at a wavelength of the maximum emission peak appearing in the emission spectrum of the phosphor B not more than 5% of an excitation intensity at a wavelength of 400 nm, wherein both of the emission spectra of the phosphors A and B are emission spectra observed by excitation with an exciting light having the same intensity at a wavelength of 400 nm, and wherein the excitation intensity of the phosphor A is an intensity observed in the excitation spectrum of the phosphor A shown in such manner that the intensity at a wavelength of 400 nm in the excitation spectrum is made equivalent to the emission intensity of the maximum emission peak of the emission spectrum of phosphor A and the excitation intensity of the phosphor B is an intensity observed in the excitation spectrum of the phosphor B shown in such manner that the intensity at a wavelength of 400 nm in the excitation spectrum is made equivalent to the emission intensity of the maximum emission peak of the emission spectrum of phosphor B.

(2) The difference between the wavelength at which the maximum emission peak is observed in the emission spectrum of the phosphor A and the wavelength at which the maximum emission peak is observed in the emission spectrum of the phosphor B is not more than 30 nm.

(3) A difference between the emission intensity of the maximum emission peak observed in the emission spectrum of the phosphor A and the emission intensity of the maximum emission peak observed in the emission spectrum of the phosphor B is in the range of 5% to 80% of the emission intensity of the maximum emission peak observed in the emission spectrum of the phosphor B.

(4) A difference between the half-width of the maximum emission peak observed in the emission spectrum of the phosphor A and the half-width of the maximum emission peak observed in the emission spectrum of the phosphor B is in the range of 5 to 80% of the half-width of the maximum emission peak observed in the emission spectrum of the phosphor A.

(5) A relationship between the emission spectrum of the phosphor A and the excitation spectrum of the phosphor B and a relationship between the excitation spectrum of the phosphor A and the emission spectrum of the phosphor B satisfy one of the following relationships 1) to 4): 1) the emission spectrum of the phosphor A and the excitation spectrum of the phosphor B do not cross each other, and the excitation spectrum of the phosphor A and the emission spectrum of the phosphor B do not cross each other;

2) the emission spectrum of the phosphor A and the excitation spectrum of the phosphor B do not cross each other, but the excitation spectrum of the phosphor A and the emission spectrum of the phosphor B cross each other under such condition that the emission intensity of the emission spectrum of the phosphor B at the point where both spectra cross each other is not more than 40% of the emission intensity of the maximum emission peak of the emission spectrum of the phosphor B;

3) the excitation spectrum of the phosphor A and the emission spectrum of the phosphor B do not cross each other, but the emission spectrum of the phosphor A and the excitation spectrum of the phosphor B cross each other under such condition that the emission intensity of the emission spectrum of the phosphor A at the point where both spectra cross each other is not more than 40% of the emission intensity of the maximum emission peak of the emission spectrum of the phosphor A; and

4) the emission spectrum of the phosphor A and the excitation spectrum of the phosphor B cross each other, and the excitation spectrum of the phosphor A and the emission spectrum of the phosphor B cross each other under such condition that sum of a percentage of the emission intensity of the emission spectrum of the phosphor A at the point where both spectra cross each other to the emission intensity of the maximum emission peak of the emission spectrum of the phosphor A and a percentage of the emission intensity of the emission spectrum of the phosphor B at the point where both spectra cross each other to the emission intensity of the maximum emission peak of the emission spectrum of the phosphor B is not more than 40%;

wherein both of the emission spectrum of the phosphor A and the emission spectrum of the phosphor B are emission spectra which are observed at excitation with an exciting light having the same intensity at a wavelength of 400 nm, and

wherein the excitation spectrum of the phosphor A is an excitation spectrum shown in such manner that an intensity at a wavelength of 400 nm is made to equivalent to the emission intensity of the maximum emission peak of the emission spectrum of the phosphor A, and the excitation spectrum of the phosphor B is an excitation spectrum shown in such manner that an intensity at a wavelength of 400 nm is made equivalent to the emission intensity of the maximum emission peak of the emission spectrum of the phosphor B.

(6) The relationship between the emission spectrum of the phosphor A and the excitation spectrum of the phosphor B and the relationship between the excitation spectrum of the phosphor A and the emission spectrum of the phosphor B satisfy the above-mentioned relationship 1).

(7) The relationship between the emission spectrum of the phosphor A and the excitation spectrum of the phosphor B and the relationship between the excitation spectrum of the phosphor A and the emission spectrum of the phosphor B satisfy the above-mentioned relationship 2) and the emission intensity of the emission spectrum of the phosphor B at the point where both spectra cross each other is not more than 20% of the emission intensity of the maximum emission peak of the emission spectrum of the phosphor B.

(8) The relationship between the emission spectrum of the phosphor A and the excitation spectrum of the phosphor B and the relationship between the excitation spectrum of the phosphor A and the emission spectrum of the phosphor B satisfy the above-mentioned relationship 3) and the emission intensity of the emission spectrum of the phosphor A at the point where both spectra cross each other is not more than 20% of the emission intensity of the maximum emission peak of the emission spectrum of the phosphor A.

(9) The relationship between the emission spectrum of the phosphor A and the excitation spectrum of the phosphor B and the relationship between the excitation spectrum of the phosphor A and the emission spectrum of the phosphor B satisfy the above-mentioned relationship 4) and the sum of a percentage of the emission intensity of the emission spectrum of the phosphor A at the point where both spectra cross each other to the emission intensity of the maximum emission peak of the emission spectrum of the phosphor A and a percentage of the emission intensity of the emission spectrum of the phosphor B at the point where both spectra cross each other to the emission intensity of the maximum emission peak of the emission spectrum of the phosphor B is not more than 20%.

(10) The phosphor A and phosphor B both show the maximum emission peak in the wavelength region of 490 to 570 nm.

(11) The phosphor A is a green light-emitting silicate phosphor having the formula of (SrBa)₂SiO₄:Eu²⁺ and the phosphor B is a green light-emitting aluminate phosphor having the formula of BaMgAl₁₀O₁₇:Eu²⁺Mn²⁺.

(12) At least one of the phosphor A and phosphor B has a fluorine-containing coat.

### EFFECTS OF THE INVENTION

The phosphor mixture of the invention is favorably employable as a visible light source for a light-emitting device such as a white LED, because it gives a light of high emission intensity and shows a color rendering property analogous to the sunlight. The emission intensity at the maximum emission peak and the half-width of the maximum emission peak can be optionally adjusted by varying a mixing ratio of the two phosphors of the analogous color-emitting properties.

### BRIEF DESCRIPTION OF DRAWINGS

FIG. 1 is a sectional view of a white LED utilizing a phosphor mixture of the invention as a visible light emitting source.

FIG. 2 shows an emission spectrum of (SrBa)₂SiO₄:Eu²⁺ and an excitation spectrum of BaMgAl₁₀O₁₇:Eu²⁺,Mn²⁺ which are used in Example 1.

FIG. 3 shows an emission spectrum of BaMgAl₁₀O₁₇:Eu²⁺,Mn²⁺ and an excitation spectrum of (SrBa)₂SiO₄:Eu²⁺ which are used in Example 1.

FIG. 4 shows an emission spectrum of the phosphor mixture prepared in Example 1.

FIG. 5 shows an emission spectrum of the green light-emitting silicate phosphor 1 and an excitation spectrum of the green light-emitting aluminate phosphor, in which both phosphors are used for the preparation of the phosphor mixture 1 in Example 3.

FIG. 6 shows an emission spectrum of the green light-emitting aluminate phosphor and an excitation spectrum of the green light-emitting silicate phosphor 1, in which both phosphors are used for the preparation of the phosphor mixture 1 in Example 3.

FIG. 7 shows emission spectra of the green light-emitting silicate phosphor 1, green light-emitting aluminate phosphor and phosphor mixture 1.

FIG. 8 shows an emission spectrum of the green light-emitting silicate phosphor 2 and an excitation spectrum of the green light-emitting aluminate phosphor, in which both phosphors are used for the preparation of the phosphor mixture 2 in Example 3.

FIG. 9 shows an emission spectrum of the green light-emitting aluminate phosphor and an excitation spectrum of the green light-emitting silicate phosphor 2, in which both phosphors are used for the preparation of the phosphor mixture 2 in Example 3.

FIG. 10 shows emission spectra of the green light-emitting silicate phosphor 2, green light-emitting aluminate phosphor and phosphor mixture 2.

FIG. 11 shows an emission spectrum of the green light-emitting silicate phosphor 2 and an excitation spectrum of the green light-emitting silicate phosphor 1, in which both phosphors are used for the preparation of the phosphor mixture 3 in Example 3.

FIG. 12 shows an emission spectrum of the green light-emitting silicate phosphor 1 and an excitation spectrum of the green light-emitting silicate phosphor 2, in which both phosphors are used for the preparation of the phosphor mixture 3 in Example 3.

FIG. 13 shows emission spectra of the green light-emitting silicate phosphor 1, green light-emitting silicate phosphor 2 and phosphor mixture 3.

### EMBODIMENTS OF THE INVENTION

The phosphor mixture of the invention contains two phosphors in which the wavelength of the maximum emission peak given by one phosphor differs from that of another phosphor by 50 nm or less. The emission strength at the wavelength of the maximum emission peak of one phosphor is higher than that of another phosphor. In contrast, the half-width of the maximum emission peak of the latter phosphor is broader than that of the former phosphor.

In the below-described explanations, the invention is further described by referring to Phosphor A giving a maximum emission peak with a broader half-width (wavelength of the maximum emission peak: λ_{A}, emission intensity at the wavelength of the maximum emission peak: I_{A}, half-width of the maximum emission peak: W_{A}) and Phosphor B giving a maximum emission peak with a higher emission intensity (wavelength of the maximum emission peak: λ_{B}, emission intensity at the wavelength of the maximum emission peak: I_{B}, half-width of the maximum emission peak: W_{B}).

The wavelength (λ_{A}) of the maximum emission peak of Phosphor A can be longer or shorter than the wavelength (λ_{B}) of the maximum emission peak of Phosphor B. Otherwise the wavelength (λ_{A}) can be the same as the wavelength (λ_{B}). The difference between the wavelength of the maximum emission peak of Phosphor A and that of Phosphor B is generally 50 nm or less (in terms of the absolute value of λ_{A}−λ_{B}), preferably 30 nm or less, most preferably 20 nm or less. The wavelength of the maximum emission peak preferably is within the wavelength range of 490 nm to 570 nm, more preferably within the wavelength range of 500nm to 550 nm.

The difference between the half-width of the maximum emission peak of Phosphor A and that of Phosphor B, namely W_{A}-W_{B}, preferably is 5% to 80% of the half-width of the maximum emission peak of Phosphor A, more preferably 20% to 80%, most preferably 30% to 80%. Otherwise, W_{A}-W_{B} can be 5% to 70% of the half-width of the maximum emission peak of Phosphor A, or 20% to 60%.

The difference between the emission intensity of the maximum emission peak of Phosphor A and that of Phosphor B, namely I_{B}-I_{A}, preferably is 5% to 80% of the emission intensity of the maximum emission peak of Phosphor B, namely I_{B}, more preferably 20% to 60%, most preferably 25% to 60%. Otherwise, I_{B}-I_{A} can be 5% to 50% of the emission intensity of the maximum emission peak of Phosphor B, or 20% to 50%.

It is preferred that the emission spectrum of Phosphor A and the excitation spectrum of Phosphor B do not overlap each other (do not cross each other) so that Phosphor B does not absorb the visible light emitted by Phosphor A and hence the emission intensity of the phosphor mixture is not largely reduced. Otherwise, if these spectra overlap each other, the overlapping are should be smaller. If the emission spectrum of Phosphor A and the excitation spectrum of Phosphor B overlap each other, the excitation intensity of Phosphor B at the wavelength (λ_{A}) of the maximum emission peak preferably is 5% or less of the excitation intensity of Phosphor B at a wavelength of 400 nm.

Similarly, it is preferred that the emission spectrum of Phosphor B and the excitation spectrum of Phosphor A do not overlap each other (do not cross each other) so that Phosphor A does not absorb the visible light emitted by Phosphor B and hence the emission intensity of the phosphor mixture is not largely reduced. Otherwise, if these spectra overlap each other, the overlapping are should be smaller. If the emission spectrum of Phosphor B and the excitation spectrum of Phosphor A overlap each other, the excitation intensity of Phosphor A at the wavelength (λ_{B}) of the maximum emission peak preferably is 5% or less of the excitation intensity of Phosphor A at a wavelength of 400 nm.

It is noted that both of the emission spectra of the phosphors A and B are emission spectra observed by excitation with an exciting light having the same intensity at a wavelength of 400 nm, and that the excitation intensity of the phosphor A is an intensity observed in the excitation spectrum of the phosphor A shown in such manner that the intensity at a wavelength of 400 nm in the excitation spectrum is made equivalent to the emission intensity of the maximum emission peak of the emission spectrum of phosphor A and the excitation intensity of the phosphor B is an intensity observed in the excitation spectrum of the phosphor B shown in such manner that the intensity at a wavelength of 400 nm in the excitation spectrum is made equivalent to the emission intensity of the maximum emission peak of the emission spectrum of phosphor B.

In the phosphor mixture of the invention, it is preferred that a relationship between the emission spectrum of the phosphor A and the excitation spectrum of the phosphor B and a relationship between the excitation spectrum of the phosphor A and the emission spectrum of the phosphor B satisfy one of the below-described relationships 1) to 4), wherein it should be noted that both of the emission spectrum of the phosphor A and the emission spectrum of the phosphor B are emission spectra which are observed at excitation with an exciting light having the same intensity at a wavelength of 400 nm, and that the excitation spectrum of the phosphor A is an excitation spectrum shown in such manner that an intensity at a wavelength of 400 nm is made to equivalent to the emission intensity of the maximum emission peak of the emission spectrum of the phosphor A, and the excitation spectrum of the phosphor B is an excitation spectrum shown in such manner that an intensity at a wavelength of 400 nm is made equivalent to the emission intensity of the maximum emission peak of the emission spectrum of the phosphor B.

1) the emission spectrum of the phosphor A and the excitation spectrum of the phosphor B do not cross each other, and the excitation spectrum of the phosphor A and the emission spectrum of the phosphor B do not cross each other;

2) the emission spectrum of the phosphor A and the excitation spectrum of the phosphor B do not cross each other, but the excitation spectrum of the phosphor A and the emission spectrum of the phosphor B cross each other under such condition that the emission intensity of the emission spectrum of the phosphor B at the point where both spectra cross each other is not more than 40% (more preferably not more than 30%, most preferably not more than 20%) of the emission intensity of the maximum emission peak of the emission spectrum of the phosphor B;

3) the excitation spectrum of the phosphor A and the emission spectrum of the phosphor B do not cross each other, but the emission spectrum of the phosphor A and the excitation spectrum of the phosphor B cross each other under such condition that the emission intensity of the emission spectrum of the phosphor A at the point where both spectra cross each other is not more than 40% (more preferably not more than 30%, most preferably not more than 20%) of the emission intensity of the maximum emission peak of the emission spectrum of the phosphor A; and

4) the emission spectrum of the phosphor A and the excitation spectrum of the phosphor B cross each other, and the excitation spectrum of the phosphor A and the emission spectrum of the phosphor B cross each other under such condition that sum of a percentage of the emission intensity of the emission spectrum of the phosphor A at the point where both spectra cross each other to the emission intensity of the maximum emission peak of the emission spectrum of the phosphor A and a percentage of the emission intensity of the emission spectrum of the phosphor B at the point where both spectra cross each other to the emission intensity of the maximum emission peak of the emission spectrum of the phosphor B is not more than 40% (more preferably not more than 30%, most preferably not more than 20%).

The phosphor mixture satisfying the above-mentioned relationship between an emission spectrum of Phosphor A and an excitation spectrum of Phosphor B and the above-mentioned relationship between an excitation spectrum of Phosphor A and an emission spectrum of Phosphor B is favorably employable as a visible light source for a white LED of the triple color-mixing type utilizing an exciting light having a wavelength in the range of 350nm to 430 nm.

The phosphor mixture of the invention generally comprises Phosphor A and Phosphor B in the ratio of 5:95 to 95:5 by weight, preferably in the ratio of 20:80 to 80:20 by weight.

The phosphor mixture of the invention preferably satisfies the following formula (I), more preferably the following formula (II):

I>0.86×{(X/(X+Y))×I_{A}+(Y/(X+Y)×I_{B})} (I)

I>0.93×{(X/(X+Y))×I_{A}+(Y/(X+Y)×I_{B})} (II)

in which I means an emission intensity of the phosphor mixture (or phosphor) at a wavelength of the maximum emission peak, and X and Y are weights of Phosphor A and Phosphor B, respectively, in the phosphor mixture.

The phosphor mixture of the invention preferably satisfies the following formula (III), more preferably the following formula (IV):

η′>0.93×{(X/(X+Y))×η′_{A}+(Y/(X+Y)×η′_{B})} (III)

η′>1.00×{(X/(X+Y))×η′_{A}+(Y/(X+Y)×η′_{B})} (IV)

in which η′ means an internal quantum efficiency of the phosphor mixture, η′_{A} means an internal quantum efficiency of Phosphor A, η′_{B} means an internal quantum efficiency of Phosphor B, and X and Y are weights of Phosphor A and Phosphor B, respectively, in the phosphor mixture.

In addition, the phosphor mixture of the invention preferably satisfies the following formula (V), more preferably the following formula (VI):

η′>0.93×{(X/(X+Y))×η_{A}+(Y/(X+Y)×η_{B})} (III)

η′>1.00×{(X/(X+Y))×η_{A}+(Y/(X+Y)×η_{B})} (IV)

in which η means an external quantum efficiency of the phosphor mixture, η_{A} means an external quantum efficiency of Phosphor A, η_{B} means an external quantum efficiency of Phosphor B, and X and Y are weights of Phosphor A and Phosphor B, respectively, in the phosphor mixture.

Examples of Phosphor A and Phosphor B include a green light-emitting silicate phosphor having the formula of (SrBa)₂SiO₄:Eu²⁺ and a green light-emitting aluminate phosphor having the formula of BaMgAl₁₀O₁₇:Eu²⁺,Mn²⁺.

Both of Phosphor A and Phosphor B can be coated with a fluorine-containing film so as to keep the phosphor from lowering of the emission intensity caused by contact with water. The fluorine-containing film is preferably formed by heating a mixture of the phosphor and ammonium fluoride. The mixture preferably contains ammonium fluoride generally in an amount of 0.5 to 15 weight parts (preferably 1 to 10 weight parts) per 100 weight parts of the phosphor. The mixture is generally heated to a temperature in the range of 200 to 600° C., preferably 200 to 500° C., more preferably 200 to 480° C., specifically preferably 300 to 480° C. The mixture is heated generally for a period of 1 to 5 hours. Phosphor A and Phosphor B can be mixed and then coated with the fluorine-containing film. Otherwise, Phosphor A and Phosphor B can be coated independently with the fluorine-containing film and then mixed to give the phosphor mixture.

The phosphor mixture is preferably heated in one of atmospheres such as surrounding atmosphere, nitrogen gas atmosphere and argon gas atmosphere. The surrounding atmosphere is preferably employed. The heating of the phosphor mixture is preferably carried out by placing the mixture in a heat-resistant vessel such as crucible covered with a lid. However, even if the heating is carried out in the atmospheric conditions, the emission intensity of the phosphor mixture hardly lowers because ammonium fluoride decomposes at a relatively low temperature and hence the surface of the phosphor mixture is treated with a decomposition gas of ammonium fluoride in advance of lowing of the emission intensity possibly caused by the heating in the atmospheric conditions.

The phosphor mixture of the invention may comprises triple color light-emitting phosphors such as a blue light-emitting phosphor, a green light-emitting phosphor and a red light-emitting phosphor. In this case, it is preferred that at least single color light-emitting phosphor satisfies the requirement of the invention, that is, the phosphor is a phosphor mixture comprising at least two phosphors in which a wavelength of the maximum emission peak of one phosphor differs from that of the maximum emission peak of another phosphor by 50 nm or less, and the maximum emission peak of the former phosphor has an emission intensity less than an emission intensity of the maximum emission peak of the latter phosphor and the maximum emission peak of the former phosphor shows a half-width broader than that of the maximum emission peak of the latter phosphor.

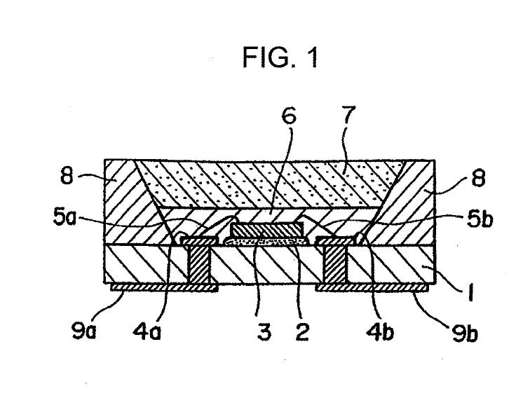

A light-emitting device employing the phosphor mixture of the invention as a visible light-emitting source is described below, referring to a white light LED shown in FIG. 1 of the accompanying drawings.

FIG. 1 is a sectional view of a white LED employing the phosphor mixture of the invention as a visible light-emitting source.

In FIG. 1, the white LED comprises a substrate 1, a semiconductor light-emitting element 3 fixed on the substrate 1 by an adhesive 2, a pair of electrodes 4a, 4b formed on the substrate 1, lead wires 5a, 5b connecting electrically the semiconductor light-emitting element 3 and the electrodes 4a, 4b, a resin layer 6 covering the semiconductor light-emitting element 3, a phosphor mixture-containing resin composition layer 7 formed on the resin layer 6, a light-reflecting material covering the surrounding of the resin layer and phosphor mixture-containing resin composition layer 7, and electroconductive wires 9a, 9b connecting electrically the electrodes 4a, 4b and the outer electric power (not shown). The substrate 1 preferably has high insulating property and high heat conductivity. Examples of the substrate 1 include substrates made of ceramics such as alumina and aluminum nitride and resinous substrates in which particles of inorganic materials such as metal oxide and glass. The semiconductor light-emitting element 3 preferably emits a light in the wavelength range of 350 nm to 430 nm upon receipt of electric energy. An example of the semiconductor light-emitting element 3 is AlGaN semiconductor light-emitting element.

The resin layer 6 is made of a transparent resin which may be epoxy resin or silicone resin. The phosphor mixture-containing resin composition layer 7 comprises a blue light-emitting phosphor, a green light-emitting phosphor and a red light-emitting phosphor dispersed in resinous binder. Each of the blue light-emitting phosphor, green light-emitting phosphor and red light-emitting phosphor is preferably has the fluorine-containing coat. The resinous binder is made of a transparent resin which may be epoxy resin or silicone resin. The light-reflecting material 8 reflects the visible light emitted by the phosphor mixture-containing resin composition layer to the outer side and hence enhances the emission efficiency. The light-reflecting material can be made of resinous material in which a metal, a white metal compound or a white pigment is dispersed. Examples of the metals, white metal compounds and white pigments include Al, Ni, Fe, Cr, Ti, Cu, Rh, Ag, Au, Pt, alumina, zirconia, titania, magnesia, zinc oxide and calcium carbonate.

In the white LED of FIG. 1, when voltage is applied to the electrodes 4a, 4b via the wires 9a, 9b, the semiconductor element 3 emits a light having a peak in the wavelength range of 350 nm to 430 nm. The emitted light excites the phosphors in the resin composition layer 7 and the phosphors emit visible lights such as blue light, green light and red light. These lights mix altogether to produce the white light.

The white LED can be manufactured in the following manner. On the substrate 1 are formed electrodes 4a, 4b in the predetermined pattern and fixed a semiconductor light-emitting element 3 by an adhesive 2. Thereafter, lead wires 5a, 5b are formed to connect the semiconductor element 3 to the electrodes 4a, 4b by wire-bonding. Around the semiconductor element 3 is fixed a light-reflecting material 8. Then, transparent resinous material is applied over the semiconductor element 3 and cured to give a resin layer 6. On the resin layer 6 is applied a phosphor mixture-containing resin composition, and the applied resin composition is cured, to give a phosphor mixture-containing resin composition layer 7.

### EXAMPLES

### Example 1

Two phosphors, namely (SrBa)₂SiO₄:Eu²⁺ (Phosphor A) and BaMgAl₁₀O₁₇:Eu²⁺,Mn²⁺ (Phosphor B), were prepared.

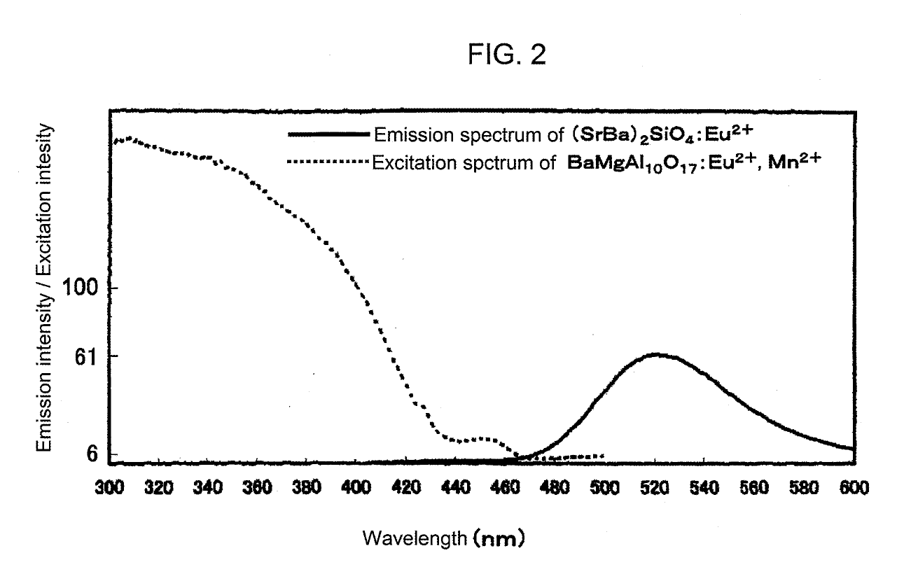

FIG. 2 shows an emission spectrum of (SrBa)₂SiO₄:Eu²⁺ and an excitation spectrum of BaMgAl₁₀O₁₇:Eu²⁺,Mn²⁺. In the emission spectrum of (SrBa)₂SiO₄:Eu²⁺, the maximum emission peak is seen at a wavelength of 521 nm, the emission intensity at 521 nm is 61 (relative value), the half-width of the maximum emission peak is 65 nm. In the excitation spectrum of BaMgAl₁₀O₁₇:Eu²⁺,Mn²⁺, the excitation intensity is 100 (relative value) at 400 nm, and 3 (relative value) at 521 nm.

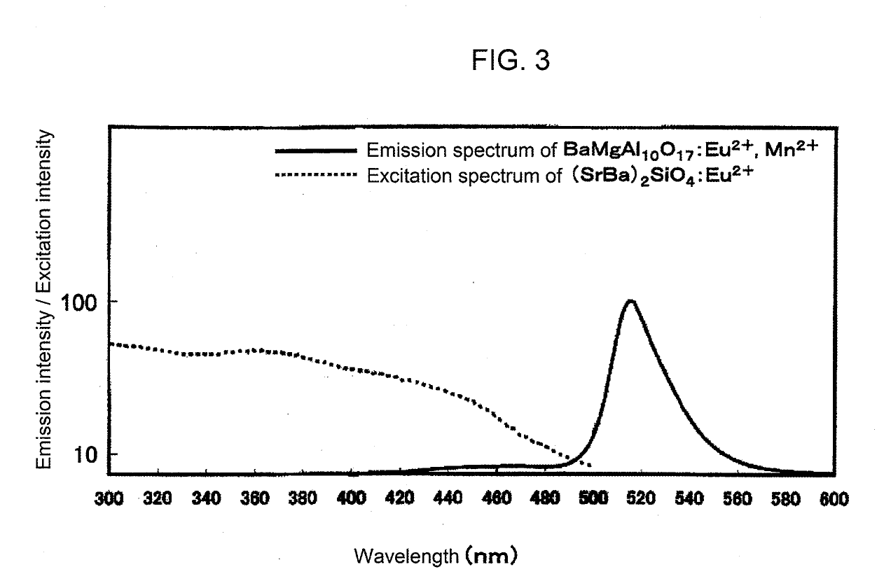

FIG. 3 shows an emission spectrum of BaMgAl₁₀O₁₇:Eu²⁺,Mn²⁺ and an excitation spectrum of (SrBa)₂SiO₄:Eu²⁺. In the emission spectrum of BaMgAl₁₀O₁₇:Eu²⁺,Mn²⁺, the maximum emission peak is seen at a wavelength of 515 nm, the emission intensity at 515 nm is 100 (relative value), the half-width of the maximum emission peak is 27 nm. In the excitation spectrum of (SrBa)₂SiO₄:Eu²⁺, the excitation intensity is 60 (relative value) at 400 nm, and 0.5 (relative value) at 515 nm.

(SrBa)₂SiO₄:Eu²⁺ and BaMgAl₁₀O₁₇:Eu²⁺,Mn²⁺ were mixed in the weight ratio set forth in the following Table 1.

TABLE 1

| No. | (SrBa)₂SiO₄:Eu²⁺:BaMgAl₁₀O₁₇:Eu²⁺, Mn²⁺ |
|---|---|
| 1 | 100:0 |
| 2 | 90:10 |
| 3 | 70:30 |
| 4 | 50:50 |
| 5 | 30:70 |
| 6 | 10:90 |
| 7 | 0:100 |

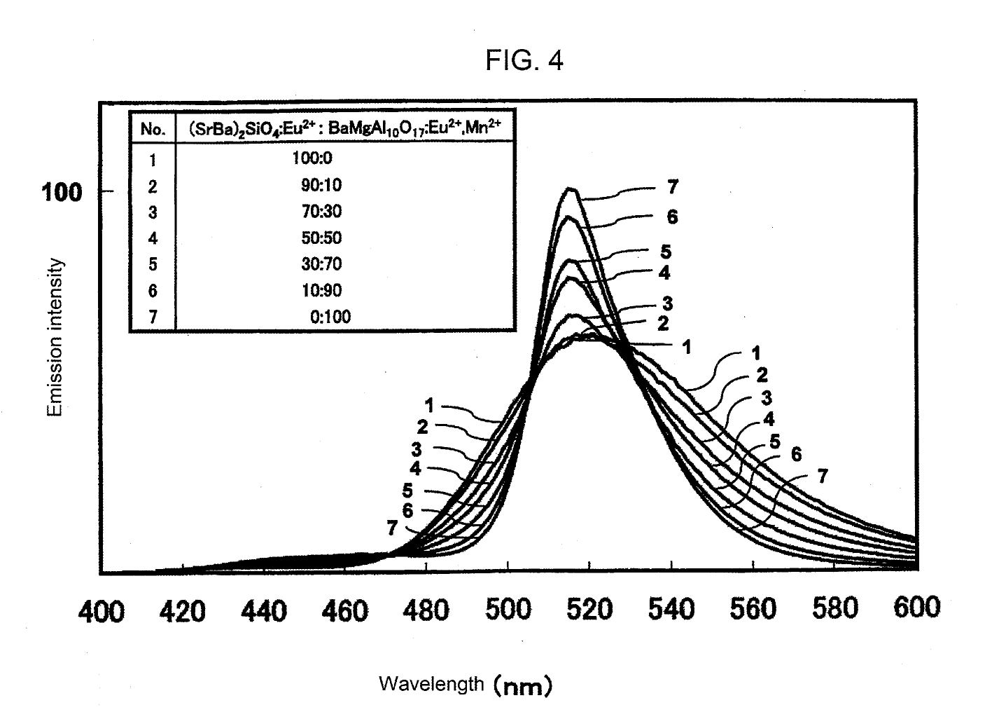

An emission of the resulting phosphor mixture was measured by applying a light having a wavelength of 400 nm to the phosphor mixture. The emission spectrum is shown in FIG. 4.

As is apparent from FIG. 4, the phosphor mixtures comprising (SrBa)₂SiO₄:Eu²⁺ and BaMgAl₁₀O₁₇:Eu²⁺,Mn²⁺ (No. 2 to 6) shows an enhanced emission intensity, as compared with the phosphor of (SrBa)₂SiO₄:Eu²⁺ alone (No. 1, corresponding to Phosphor A), and an emission peak having a half-width broader than the phosphor of BaMgAl₁₀O₁₇:Eu²⁺,Mn²⁺ alone (No.7 corresponding to Phosphor B).

### Example 2

(SrBa)₂SiO₄:Eu²⁺ and BaMgAl₁₀O₁₇:Eu²⁺,Mn²⁺ were mixed in the weight ratio of 50:50 to prepare a phosphor mixture. The thus prepared phosphor mixture (1) was immediately subjected to determination of its emission intensity.

Thereafter, 100 parts by weight of the phosphor mixture are mixed with 10 parts by weight of ammonium fluoride. The resulting mixture was placed in an alumina setter. The setter was covered with a lid and heated in an electric furnace at 500° C. for 6 hours. The phosphor mixture (2) which was thus heated in the presence of ammonium fluoride was subjected to determination of its emission intensity. The thus heated phosphor mixture was kept in a thermohygrostat controlled to 60° C., 80%RH for 500 hours. The thus treated phosphor mixture (3) was then subjected to determination of its emission intensity.

In Table 2, the determined emission intensity is set forth for the phosphors (1), (2) and (3). The emission intensity is shown in terms of a value relative to 100 assigned to the emission intensity of the phosphor (1).

### [Method for Determination of Emission Intensity]

The phosphor mixture was irradiated with a light (wavelength: 400 nm) emitted by a xenon lamp, and the emission spectrum was obtained. The height of the maximum emission peak seen in the emission spectrum was determined to give the emission intensity.

### Reference Example 1

The procedures of Example 2 were repeated except that the phosphor mixture was not heated in the presence of ammonium fluoride and kept in a thermohygrostat controlled to 60° C., 80%RH for 500 hours. The thus treated phosphor mixture was then subjected to determination of its emission intensity.

The determined emission intensity is set forth in Table 2. The emission intensity is shown in terms of a value relative to 100 assigned to the emission intensity of the phosphor (1).

TABLE 2

| | Phosphor (1) | Phosphor (2) | Phosphor (3) |
|---|---|---|---|
| Example 2 | 100 | 100 | 99 |
| Ref. Ex. 1 | 100 | — | 79 |

Remarks:
Phosphor (1): phosphor mixture just after its pre-paration
Phosphor (2): phosphor mixture after being heated in the presence of ammonium fluoride
Phosphor (3): phosphor mixture after being kept in a thermohygrostat

As is apparent from the data set forth in Table 2, Phosphor (2) of Example 2, namely the phosphor mixture having a fluorine-containing coat (prepared by heating in the presence of ammonium fluoride), shows a high emission intensity after being kept in a thermohygrostat, as compared with Phosphor (1) of Reference Example 1, namely the phosphor mixture having no fluorine-containing coat. This means that the phosphor mixture having a fluorine-containing coat is resistant to lowering of its emission intensity which is caused by contact with water component (water vapor).

### Example 3

Three phosphors, namely Sr_{1.01}Eu_{0.04}Ba_{0.95}SiO₄ (Green light-emitting silicate phosphor 1), Sr_{1.46}Eu_{0.04}Ba_{0.50}SiO₄ (Green light-emitting silicate phosphor 2) and Ba_{0.75}Eu_{0.25}Mg_{0.65}Mn_{0.35}Al₁₀O₁₇ (Green light-emitting aluminate phosphor) were prepared and subjected to determination of emission spectrum. In Table 3, the wavelength, emission intensity and half-width of the maximum emission peak is set forth for each phosphor. The emission intensity is shown in terms of a value relative to 100 assigned to the emission intensity of the maximum emission peak seen in the emission spectrum of Green light-emitting aluminate phosphor.

TABLE 3

| | Peak | Emission | Half- |
|---|---|---|---|
| | wavelength | intensity | width |
| Silicate phosphor 1 | 523 nm | 62 | 65 |
| Silicate phosphor 2 | 545 nm | 49 | 90 |
| Aluminate phosphor | 516 nm | 100 | 27 |

Remarks:
Silicate phosphor 1: Green light-emitting silicate phosphor 1
Silicate phosphor 2: Green light-emitting silicate phosphor 2
Aluminate phosphor: Green light-emitting aluminate phosphor

### (Preparation of Phosphor Mixture 1)

Green light-emitting silicate phosphor 1 (corresponding to Phosphor A) and Green light-emitting aluminate phosphor (corresponding to Phosphor B) were mixed in a weight ratio of 50:50, to prepare a phosphor mixture 1. The emission spectrum was obtained for each of the silicate phosphor 1, aluminate phosphor, and phosphor mixture 1, using an exciting light having the same intensity at 400 nm. Further, the excitation spectrum was obtained for each of the silicate phosphor 1 and aluminate phosphor.

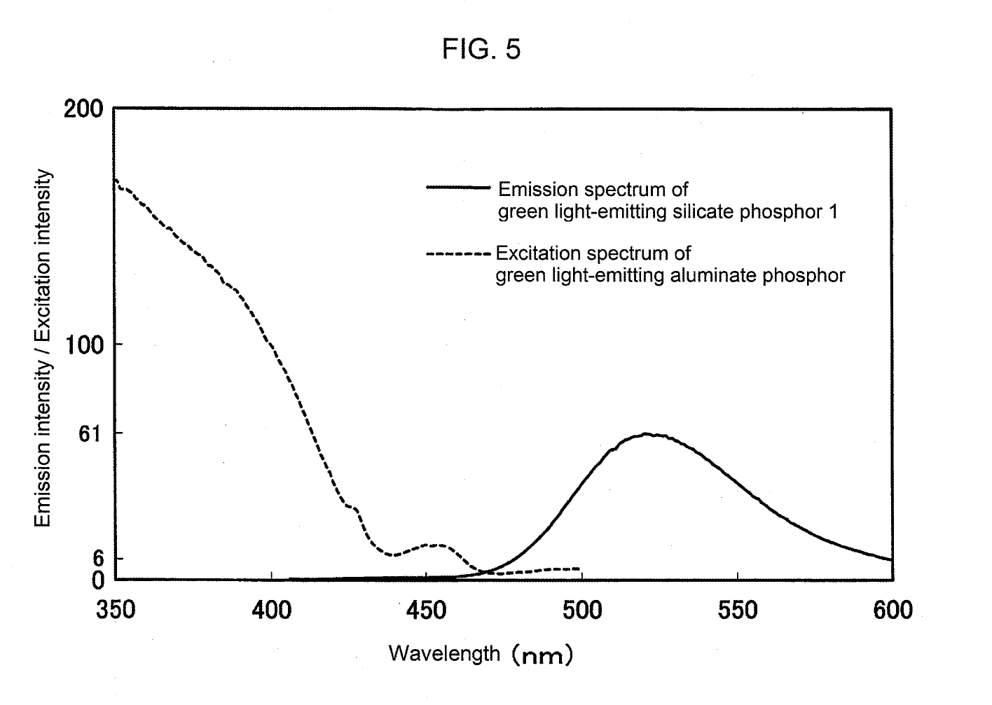

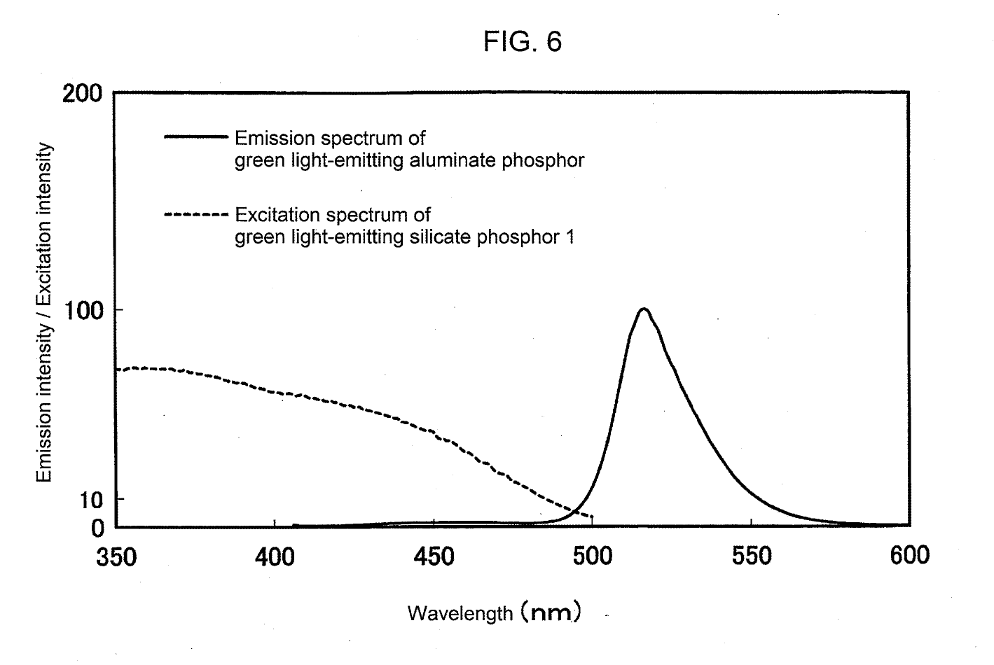

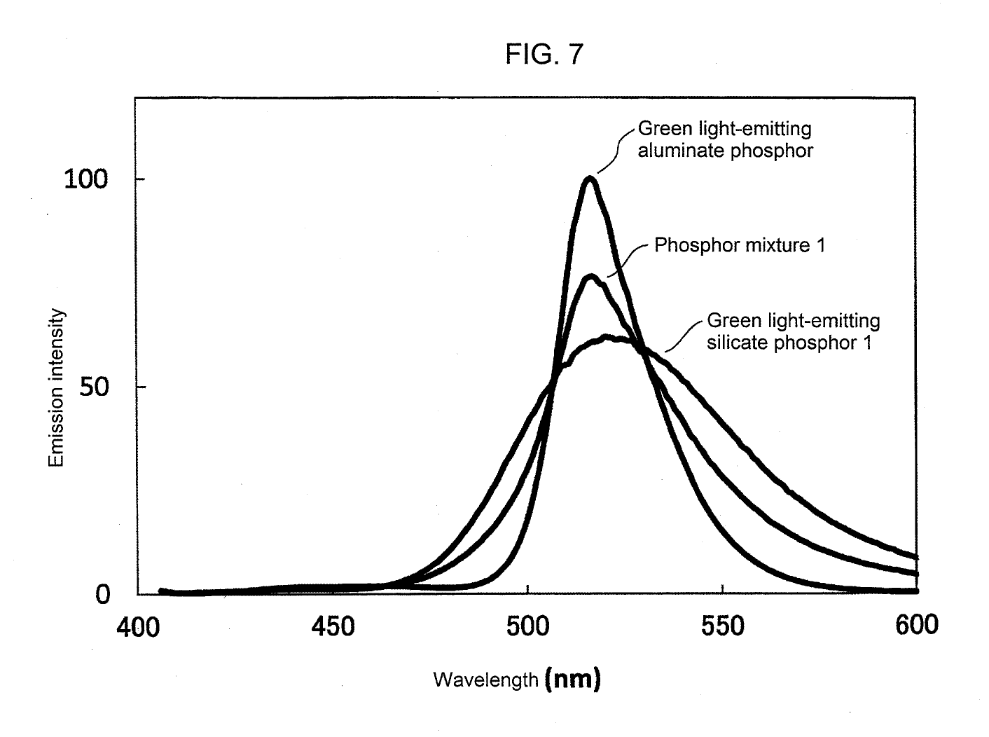

In FIG. 5, the emission spectrum of the silicate phosphor 1 and the excitation spectrum of the aluminate phosphor are shown. In FIG. 6, the excitation spectrum of the silicate phosphor 1 and the emission spectrum of the aluminate phosphor are shown. In FIG. 7, the emission spectra of the silicate phosphor 1, aluminate phosphor and phosphor mixture 1 are shown.

In FIG. 5 showing the emission spectrum of the silicate phosphor 1, the level of the emission intensity 100 on the axis of ordinates corresponds to the height of emission intensity of the maximum emission peak seen in the emission spectrum of the aluminate phosphor. The excitation spectrum of the aluminate phosphor is shown in such manner that the intensity at 400 nm corresponds to the emission intensity of the maximum emission peak seen in the emission spectrum of the aluminate phosphor.

From FIG. 5, it is understood that the emission spectrum of the silicate phosphor 1 and the excitation spectrum of the aluminate phosphor cross each other, and that the emission intensity of the silicate phosphor 1 is less than 6 at the crossing. In FIG. 5, the emission intensity of the maximum emission peak of the silicate phosphor 1 is 61. Therefore, the emission intensity of the silicate phosphor 1 at the crossing is less than 10% of the emission intensity of the maximum emission peak of the silicate phosphor 1.

In FIG. 6 showing the emission spectrum of the aluminate phosphor, the level of the emission intensity 100 on the axis of ordinates corresponds to the height of emission intensity of the maximum emission peak seen in the emission spectrum of the aluminate phosphor. The excitation spectrum of the silicate phosphor 1 is shown in such manner that the intensity at 400 nm corresponds to the emission intensity of the maximum emission peak seen in the emission spectrum of the silicate phosphor 1.

From FIG. 6, it is understood that the emission spectrum of the aluminate phosphor and the excitation spectrum of the silicate phosphor 1 cross each other, and that the emission intensity of the aluminate phosphor is less than 10 at the crossing. In FIG. 6, the emission intensity of the maximum emission peak of the aluminate phosphor is 100. Therefore, the emission intensity of the aluminate phosphor at the crossing is less than 10% of the emission intensity of the maximum emission peak of the aluminate phosphor.

From FIG. 7, it is understood that the phosphor mixture 1 shows high emission intensity, as compared with the emission intensity given by the silicate phosphor 1 (Phosphor A) and has an emission peak with broad half-width, as compared with an emission peak seen in the emission spectrum of the aluminate phosphor (Phosphor B).

### (Preparation of Phosphor Mixture 2)

Green light-emitting silicate phosphor 2 (corresponding to Phosphor A) and Green light-emitting aluminate phosphor (corresponding to Phosphor B) were mixed in a weight ratio of 50:50, to prepare a phosphor mixture 2. The emission spectrum was obtained for each of the silicate phosphor 2, aluminate phosphor, and phosphor mixture 2, using an exciting light having the same intensity at 400 nm. Further, the excitation spectrum was obtained for each of the silicate phosphor 2 and aluminate phosphor.

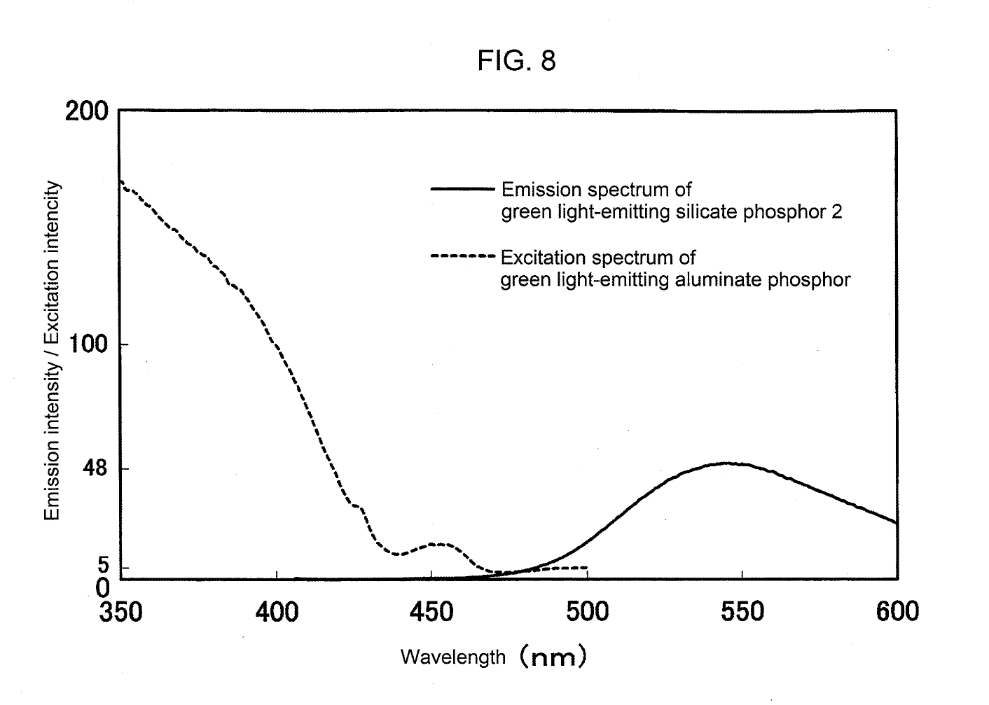

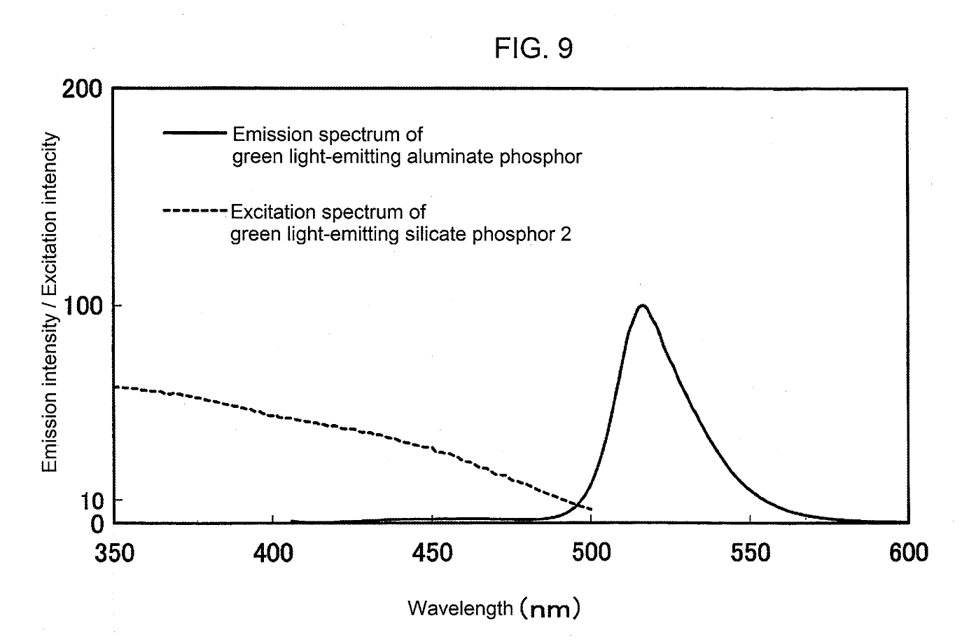

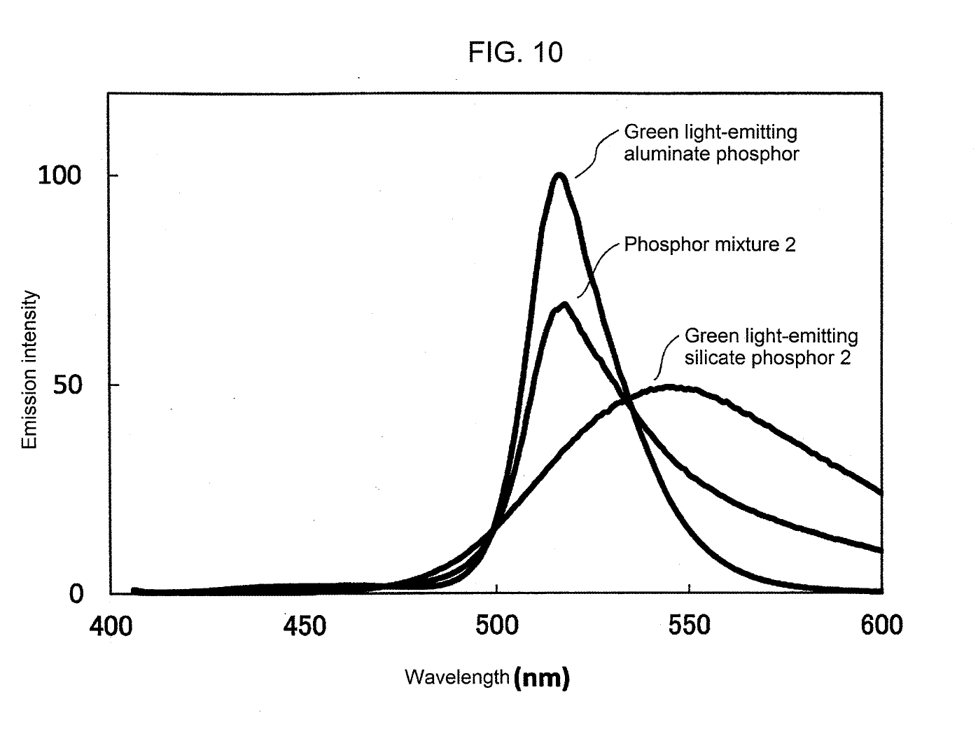

In FIG. 8, the emission spectrum of the silicate phosphor 2 and the excitation spectrum of the aluminate phosphor are shown. In FIG. 9, the excitation spectrum of the silicate phosphor 2 and the emission spectrum of the aluminate phosphor are shown. In FIG. 10, the emission spectra of the silicate phosphor 2, aluminate phosphor and phosphor mixture 2 are shown.

In FIG. 8 showing the emission spectrum of the silicate phosphor 2, the level of the emission intensity 100 on the axis of ordinates corresponds to the height of emission intensity of the maximum emission peak seen in the emission spectrum of the aluminate phosphor. The excitation spectrum of the aluminate phosphor is shown in such manner that the intensity at 400 nm corresponds to the emission intensity of the maximum emission peak seen in the emission spectrum of the aluminate phosphor.

From FIG. 8, it is understood that the emission spectrum of the silicate phosphor 2 and the excitation spectrum of the aluminate phosphor cross each other, and that the emission intensity of the silicate phosphor 2 is less than 5 at the crossing. In FIG. 8, the emission intensity of the maximum emission peak of the silicate phosphor 2 is 48. Therefore, the emission intensity of the silicate phosphor 2 at the crossing is less than 10% of the emission intensity of the maximum emission peak of the silicate phosphor 2.

In FIG. 9 showing the emission spectrum of the aluminate phosphor, the level of the emission intensity 100 on the axis of ordinates corresponds to the height of emission intensity of the maximum emission peak seen in the emission spectrum of the aluminate phosphor. The excitation spectrum of the silicate phosphor 2 is shown in such manner that the intensity at 400 nm corresponds to the emission intensity of the maximum emission peak seen in the emission spectrum of the silicate phosphor 2.

From FIG. 9, it is understood that the emission spectrum of the aluminate phosphor and the excitation spectrum of the silicate phosphor 2 cross each other, and that the emission intensity of the aluminate phosphor is less than 10 at the crossing. In FIG. 9, the emission intensity of the maximum emission peak of the aluminate phosphor is 100. Therefore, the emission intensity of the aluminate phosphor at the crossing is less than 10% of the emission intensity of the maximum emission peak of the aluminate phosphor.

From FIG. 10, it is understood that the phosphor mixture 2 shows high emission intensity, as compared with the emission intensity given by the silicate phosphor 2 (Phosphor A) and has an emission peak with broad half-width, as compared with an emission peak seen in the emission spectrum of the aluminate phosphor (Phosphor B).

### (Preparation of Phosphor Mixture 3)

Green light-emitting silicate phosphor 1 (corresponding to Phosphor B) and Green light-emitting silicate phosphor 2 (corresponding to Phosphor A) were mixed in a weight ratio of 50:50, to prepare a phosphor mixture 3. The emission spectrum was obtained for each of the silicate phosphor 1, silicate phosphor 2, and phosphor mixture 3, using an exciting light having the same intensity at 400 nm. Further, the excitation spectrum was obtained for each of the silicate phosphor 1 and silicate phosphor 1.

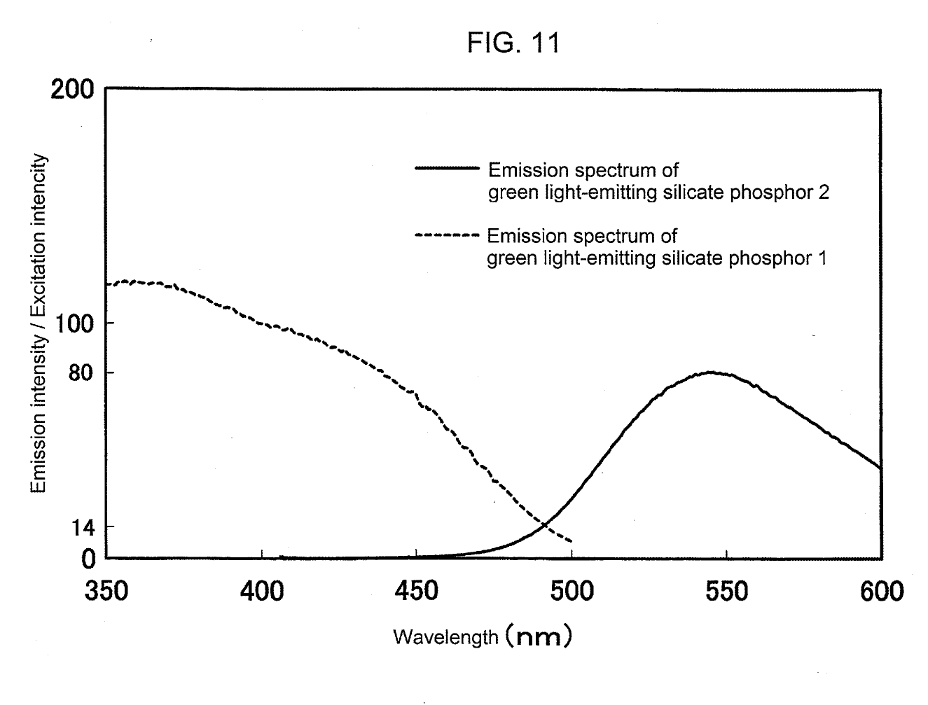

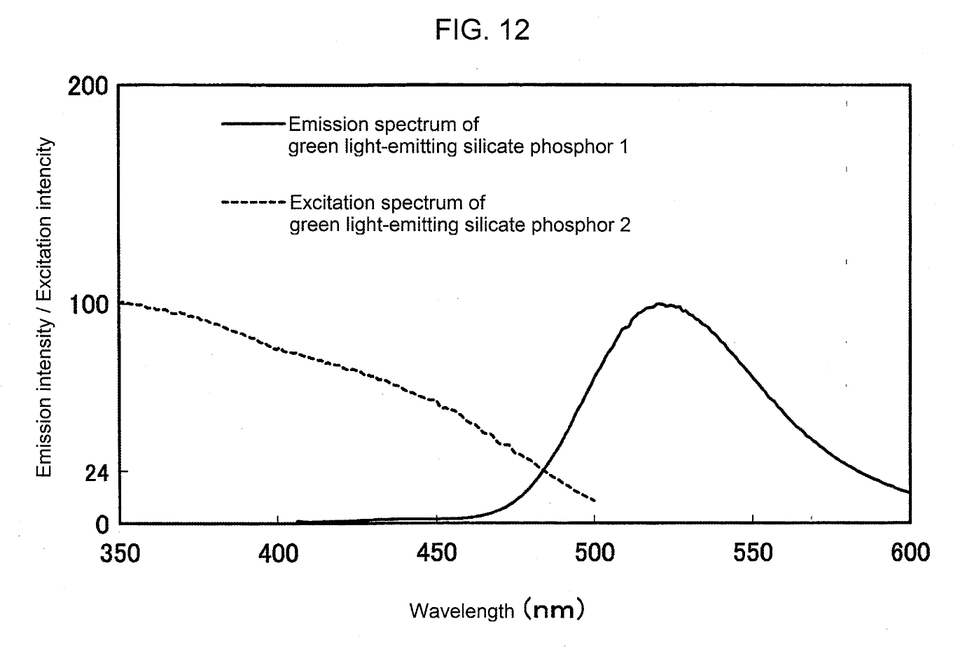

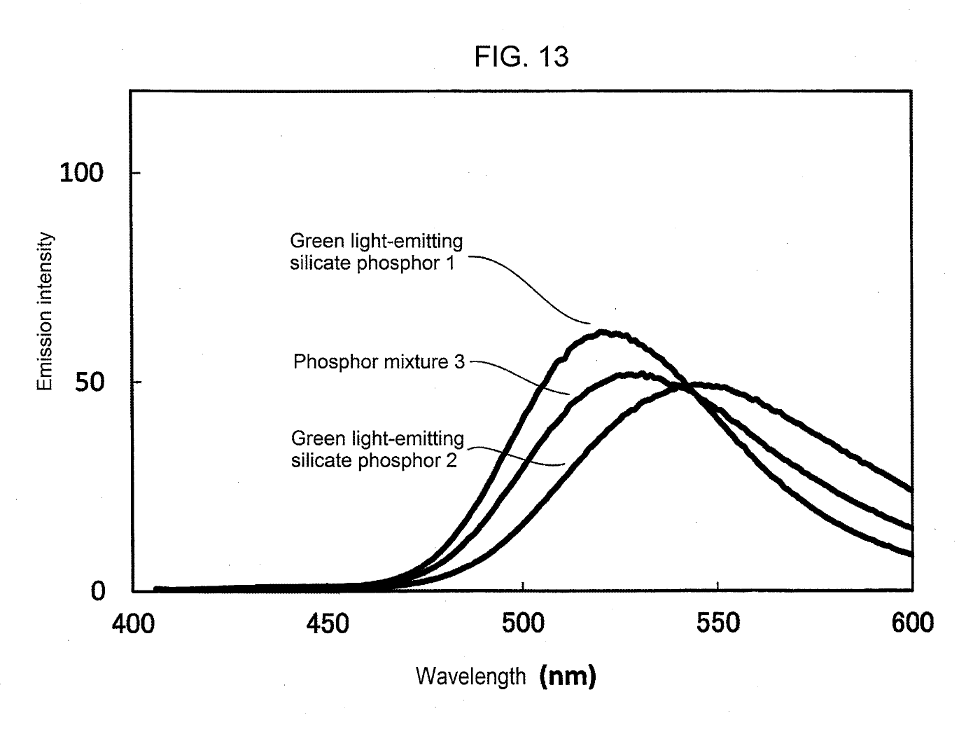

In FIG. 11, the emission spectrum of the silicate phosphor 2 and the excitation spectrum of the silicate phosphor 1 are shown. In FIG. 12, the emission spectrum of the silicate phosphor 1 and the excitation spectrum of the silicate phosphor 2 are shown. In FIG. 13, the emission spectra of the silicate phosphor 1, silicate phosphor 2 and phosphor mixture 3 are shown.

In FIG. 11 showing the emission spectrum of the silicate phosphor 2, the level of the emission intensity 100 on the axis of ordinates corresponds to the height of emission intensity of the maximum emission peak seen in the emission spectrum of the silicate phosphor 1. The excitation spectrum of the silicate phosphor 1 is shown in such manner that the intensity at 400 nm corresponds to the emission intensity of the maximum emission peak seen in the emission spectrum of the silicate phosphor 1.

From FIG. 11, it is understood that the emission spectrum of the silicate phosphor 2 and the excitation spectrum of the silicate phosphor 1 cross each other, and that the emission intensity of the silicate phosphor 2 is 14 at the crossing. In FIG. 11, the emission intensity of the maximum emission peak of the silicate phosphor 2 is 80. Therefore, the emission intensity of the silicate phosphor 2 at the crossing is 18%(=100×14/80) of the emission intensity of the maximum emission peak of the silicate phosphor 2.

In FIG. 12 showing the emission spectrum of the silicate phosphor 1, the level of the emission intensity 100 on the axis of ordinates corresponds to the height of emission intensity of the maximum emission peak seen in the emission spectrum of the silicate phosphor 1. The excitation spectrum of the silicate phosphor 2 is shown in such manner that the intensity at 400 nm corresponds to the emission intensity of the maximum emission peak seen in the emission spectrum of the silicate phosphor 2.

From FIG. 12, it is understood that the emission spectrum of the silicate phosphor 1 and the excitation spectrum of the silicate phosphor 2 cross each other, and that the emission intensity of the silicate phosphor is 24 at the crossing. In FIG. 12, the emission intensity of the maximum emission peak of the silicate phosphor 1 is 100. Therefore, the emission intensity of the silicate phosphor 1 at the crossing is 24%(=100×24/100) of the emission intensity of the maximum emission peak of the silicate phosphor 1. Therefore, the sum of the percentage of emission intensity of the emission spectrum of the silicate phosphor 1 at the wavelength where it crosses with the excitation spectrum of the silicate phosphor 2, to the emission intensity of the maximum emission peak of the emission spectrum of the silicate phosphor 1, namely 24%, and the percentage of emission intensity of the emission spectrum of the silicate phosphor 1 at the wavelength where it crosses with the excitation spectrum of the silicate phosphor 1, to the emission intensity of the maximum emission peak of the emission spectrum of the silicate phosphor 2, namely 18%, is 42%.

From FIG. 13, it is understood that the phosphor mixture 3 shows high emission intensity, as compared with the emission intensity given by the silicate phosphor 2 (Phosphor A) and has an emission peak with broad half-width, as compared with an emission peak seen in the emission spectrum of the silicate phosphor 1 (Phosphor B).

### (Evaluation of Emission Efficiency of Phosphor Mixture)

The phosphor mixtures 1 to 3, silicate phosphor 1, silicate phosphor 2 and aluminate phosphor are subjected to determinations of internal quantum efficiency and external quantum efficiency in the below-mentioned manner. The results are set forth in Table 4.

### (Determinations of Internal Quantum Efficiency and External Quantum Efficiency)

The specimen (phosphor mixture or phosphor) is placed in a holder, and the holder is attached to a fluorescence spectrophotometer (FP6500, available from Jusco Engineering). In the fluorescence spectrophotometer-meter, ultraviolet rays (wavelength: 400 nm) are applied to the specimen, to obtain an emission spectrum. From the emission spectrum, an integrated value (L) of emission spectrum in the wavelength region of 380-410 nm and an integrated value (E) of emission spectrum in the wavelength region of 410-700 nm are obtained. Then, a reference material (white barium sulfate plate) is attached to the fluorescence spectrophotometer. In the fluorescence spectrophotometer, the same ultraviolet rays are applied to the reference material, to obtain an emission spectrum. From the emission spectrum, an integrated value (R) of emission spectrum in the wavelength region of 380-410 nm is obtained.

The internal quantum efficiency and external quantum efficiency are obtained from L, E and R by calculation utilizing the following formulas:

Internal quantum efficiency=100×E/(R−L)

External quantum efficiency=100×E/R

TABLE 4

| | Internal quantum | External quantum |
|---|---|---|
| Specimen | efficiency (%) | efficiency (%) |
| Phosphor mixture 1 | 65.1 | 47.0 |
| Silicate phosphor 1 | 71.3 | 56.3 |
| Aluminate phosphor | 54.1 | 35.6 |
| Estimated value | 62.7 | 46.0 |
| Phosphor mixture 2 | 65.6 | 46.5 |
| Silicate phosphor 2 | 71.0 | 56.2 |
| Aluminate phosphor | 54.1 | 35.6 |
| Estimated value | 62.6 | 45.9 |
| Phosphor mixture 3 | 66.3 | 52.4 |
| Silicate phosphor 1 | 71.3 | 56.3 |
| Silicate phosphor 2 | 71.0 | 56.2 |
| Estimated value | 71.2 | 56.3 |

Remarks:
Phosphor mixture 1 = mixture of silicate phosphor 1 and aluminate phosphor (50:50, by weight)
Phosphor mixture 2 = mixture of silicate phosphor 2 and aluminate phosphor (50:50, by weight)
Phosphor mixture 3 = mixture of silicate phosphor 1 and silicate phosphor 2 (50:50, by weight)
Silicate phosphor 1: Sr_{1.01}Eu_{0.04}Ba_{0.95}SiO₄
Silicate phosphor 2: Sr_{1.46}Eu_{0.04}Ba_{0.50}SiO₄
Aluminate phosphor: Ba_{0.75}Eu_{0.25}Mg_{0.65}Mn_{0.35}Al₁₀O₁₇

In Table 4, the estimated value is a value estimated for a mixture of the two phosphors in a weight ratio of 50:50. For instance, the estimated internal quantum efficiency for the phosphor mixture 1 is obtained by calculation according to the formula of {[(internal quantum efficiency of silicate phosphor 1)×50+(internal quantum efficiency of aluminate phosphor)×50]/100}.

From the results set forth in Table 4, it is understood that both of the internal quantum efficiency and external quantum efficiency are higher than the estimated values for the phosphor mixtures 1 and 2, while both of the internal quantum efficiency and external quantum efficiency are lower than the estimated values for the phosphor mixture 3.

The reason of the lowering of the internal quantum efficiency and external quantum efficiency for the phosphor mixture 3 is thought as follows: The emission spectrum of the silicate phosphor 1 and the excitation spectrum of the silicate phosphor 2 as well as the excitation spectrum of the silicate phosphor 1 and the emission spectrum of the silicate phosphor 2 overlap with a large overlapping area, as compared with the corresponding overlapping seen in the emission spectrum and excitation spectrum of the silicate phosphor 1 or 2 and aluminate phosphor of the phosphor mixture 1 or 2. Therefore, in the phosphor mixture 3, the visible light emitted by the silicate phosphor 1 is absorbed by the silicate phosphor 2, and the visible light emitted by the silicate phosphor 2 is absorbed by the silicate phosphor 1.

What is claimed is:

1. A phosphor mixture comprising at least two phosphors A and B which give an emission spectrum having the maximum emission peak in the visible region, wherein a wavelength of the maximum emission peak of the phosphor A differs from that of the maximum emission peak of the phosphor B by not more than 50 nm, and wherein the maximum emission peak of the phosphor A has an emission intensity less than an emission intensity of the maximum emission peak of the phosphor B and the maximum emission peak of the phosphor A shows a half-width broader than a half-width of the maximum emission peak of the phosphor B.

2. The phosphor mixture of claim 1, in which the phosphor B has an excitation intensity at a wavelength of the maximum emission peak appearing in the emission spectrum of the phosphor A not more than 5% of an excitation intensity at a wavelength of 400 nm and the phosphor A has an excitation intensity at a wavelength of the maximum emission peak appearing in the emission spectrum of the phosphor B not more than 5% of an excitation intensity at a wavelength of 400 nm, wherein both of the emission spectra of the phosphors A and B are emission spectra observed by excitation with an exciting light having the same intensity at a wavelength of 400 nm, and wherein the excitation intensity of the phosphor A is an intensity observed in the excitation spectrum of the phosphor A shown in such manner that the intensity at a wavelength of 400 nm in the excitation spectrum is made equivalent to the emission intensity of the maximum emission peak of the emission spectrum of phosphor A and the excitation intensity of the phosphor B is an intensity observed in the excitation spectrum of the phosphor B shown in such manner that the intensity at a wavelength of 400 nm in the excitation spectrum is made equivalent to the emission intensity of the maximum emission peak of the emission spectrum of phosphor B.

3. The phosphor mixture of claim 1, in which the difference between the wavelength at which the maximum emission peak is observed in the emission spectrum of the phosphor A and the wavelength at which the maximum emission peak is observed in the emission spectrum of the phosphor B is not more than 30 nm.

4. The phosphor mixture of claim 1, in which a difference between the emission intensity of the maximum emission peak observed in the emission spectrum of the phosphor A and the emission intensity of the maximum emission peak observed in the emission spectrum of the phosphor B is in the range of 5% to 80% of the emission intensity of the maximum emission peak observed in the emission spectrum of the phosphor B.

5. The phosphor mixture of claim 1, in which a difference between the half-width of the maximum emission peak observed in the emission spectrum of the phosphor A and the half-width of the maximum emission peak observed in the emission spectrum of the phosphor B is in the range of 5 to 80% of the half-width of the maximum emission peak observed in the emission spectrum of the phosphor A.

6. The phosphor mixture of claim 1, in which a relationship between the emission spectrum of the phosphor A and the excitation spectrum of the phosphor B and a relationship between the excitation spectrum of the phosphor A and the emission spectrum of the phosphor B satisfy one of the following relationships (1) to (4):
(1) the emission spectrum of the phosphor A and the excitation spectrum of the phosphor B do not cross each other, and the excitation spectrum of the phosphor A and the emission spectrum of the phosphor B do not cross each other;
(2) the emission spectrum of the phosphor A and the excitation spectrum of the phosphor B do not cross each other, but the excitation spectrum of the phosphor A and the emission spectrum of the phosphor B cross each other under such condition that the emission intensity of the emission spectrum of the phosphor B at the point where both spectra cross each other is not more than 40% of the emission intensity of the maximum emission peak of the emission spectrum of the phosphor B;
(3) the excitation spectrum of the phosphor A and the emission spectrum of the phosphor B do not cross each other, but the emission spectrum of the phosphor A and the excitation spectrum of the phosphor B cross each other under such condition that the emission intensity of the emission spectrum of the phosphor A at the point where both spectra cross each other is not more than 40% of the emission intensity of the maximum emission peak of the emission spectrum of the phosphor A; and
(4) the emission spectrum of the phosphor A and the excitation spectrum of the phosphor B cross each other, and the excitation spectrum of the phosphor A and the emission spectrum of the phosphor B cross each other under such condition that sum of a percentage of the emission intensity of the emission spectrum of the phosphor A at the point where both spectra cross each other to the emission intensity of the maximum emission peak of the emission spectrum of the phosphor A and a percentage of the emission intensity of the emission spectrum of the phosphor B at the point where both spectra cross each other to the emission intensity of the maximum emission peak of the emission spectrum of the phosphor B is not more than 40%;
wherein both of the emission spectrum of the phosphor A and the emission spectrum of the phosphor B are emission spectra which are observed at excitation with an exciting light having the same intensity at a wavelength of 400 nm, and
wherein the excitation spectrum of the phosphor A is an excitation spectrum shown in such manner that an intensity at a wavelength of 400 nm is made to equivalent to the emission intensity of the maximum emission peak of the emission spectrum of the phosphor A, and the excitation spectrum of the phosphor B is an excitation spectrum shown in such manner that an intensity at a wavelength of 400 nm is made equivalent to the emission intensity of the maximum emission peak of the emission spectrum of the phosphor B.

7. The phosphor mixture of claim 6, in which the relationship between the emission spectrum of the phosphor A and the excitation spectrum of the phosphor B and the relationship between the excitation spectrum of the phosphor A and the emission spectrum of the phosphor B satisfy the relationship (1).

8. The phosphor mixture of claim 6, in which the relationship between the emission spectrum of the phosphor A and the excitation spectrum of the phosphor B and the relationship between the excitation spectrum of the phosphor A and the emission spectrum of the phosphor B satisfy the relationship (2) and the emission intensity of the emission spectrum of the phosphor B at the point where both spectra cross each other is not more than 20% of the emission intensity of the maximum emission peak of the emission spectrum of the phosphor B.

9. The phosphor mixture of claim 6, in which the relationship between the emission spectrum of the phosphor A and the excitation spectrum of the phosphor B and the relationship between the excitation spectrum of the phosphor A and the emission spectrum of the phosphor B satisfy the relationship (3) and the emission intensity of the emission spectrum of the phosphor A at the point where both spectra cross each other is not more than 20% of the emission intensity of the maximum emission peak of the emission spectrum of the phosphor A.

10. The phosphor mixture of claim 6, in which the relationship between the emission spectrum of the phosphor A and the excitation spectrum of the phosphor B and the relationship between the excitation spectrum of the phosphor A and the emission spectrum of the phosphor B satisfy the relationship (4) and the sum of a percentage of the emission intensity of the emission spectrum of the phosphor A at the point where both spectra cross each other to the emission intensity of the maximum emission peak of the emission spectrum of the phosphor A and a percentage of the emission intensity of the emission spectrum of the phosphor B at the point where both spectra cross each other to the emission intensity of the maximum emission peak of the emission spectrum of the phosphor B is not more than 20%.

11. The phosphor mixture of claim 1, in which the phosphor A and phosphor B both show the maximum emission peak in the wavelength region of 490 to 570 nm.

12. The phosphor mixture of claim 1, in which the phosphor A is a green light-emitting silicate phosphor having the formula of (SrBa)₂SiO₄:Eu²⁺ and the phosphor B is a green light-emitting aluminate phosphor having the formula of BaMgAl₁₀O₁₇ : Eu²⁺, Mn²⁺.

13. The phosphor mixture of claim 1, in which at least one of the phosphor A and phosphor B has a fluorine-containing coat.
